(19) United States
(12) Patent Application Publication
(10) Pub. No.: US 2007/0095379 A1
(43) Pub. Date: May 3, 2007

(54) Thermoelectric generator

(76) Inventors: Mahmoud A. Taher, Peoria, IL (US); Ronald Dupree, Washington, IL (US); Dong Fei, Peoria, IL (US); Scott David Garner, Lititz, PA (US)

Correspondence Address: CATERPILLAR/FINNEGAN, HENDERSON, L.L.P., 901 New York Avenue, NW, WASHINGTON, DC, 20001-4413, US

(21) Appl. No.: 11/262,623

(22) Filed: Oct. 31, 2005

(51) Int. Cl. H01L 35/30

(52) U.S. Cl. 136/205

(57) ABSTRACT

A thermoelectric power unit is provided. The power unit may include at least one thermoelectric device. A first fluid passage may be disposed on a first side of the thermoelectric device and may be configured to receive a hot exhaust stream. The power unit may further include a plurality of heat pipes configured to focus thermal energy from a fluid flowing through the first passage toward the first side of the thermoelectric device. A second fluid passage may be disposed on a second side of the thermoelectric device opposite of the first fluid passage and configured to conduct thermal energy away from the thermoelectric device.

### U.S. GOVERNMENT RIGHTS

This invention was made with government support under the terms of Contract No. DE-FC26-04NT42280 awarded by the Department of Energy. The government may have certain rights in this invention.

### TECHNICAL FIELD

This disclosure pertains generally to thermoelectric power units, and more particularly to thermoelectric power units for use with hot exhaust gas streams.

### BACKGROUND

Combustion of fossil fuels releases a substantial amount of useful energy, some of which can be converted into mechanical energy to power machines such as trucks, trains, and heavy equipment. In addition, some of the energy is released as thermal energy. A small amount of the thermal energy may be used for various machine operations, but much of the thermal energy is wasted as it is released in machine exhaust gases. To improve overall machine efficiency, it would be useful to convert wasted thermal energy from engine exhaust gases into a useful form.

Thermoelectric power units can be used to convert thermal energy into electrical energy, which may be used to power a variety of different machine operations. Thermoelectric power units can include a variety of different thermoelectric devices, which include electrically-active materials. To produce electricity, a temperature differential is produced across the material using a heat source on one side, and a cooling system on the other. The efficiency and total power output of the thermoelectric power unit may be dependent on a number of factors including, for example, the type of thermoelectric materials selected and the total temperature difference across the material. Although some thermoelectric power units are currently available, more efficient, smaller devices with higher power densities are needed.

One system for thermoelectric power production is described in U.S. Pat. No. 4,448,028, which issued to Chao on May 15, 1984 (hereinafter the '028 patent). The '028 patent provides a thermoelectric system for generating electrical energy. The system includes a thermoelectric power unit disposed between and in thermally transmissive contact with both a heat pipe on one side and a flowing cold fluid on the other side.

Although the thermoelectric system of the '028 patent may provide suitable power production, the system of the '028 patent may have several drawbacks. For example, the system of the '028 patent may require a substantial amount of thermoelectric material, which can be very expensive. In addition, the system of the '028 patent may be too large for use with certain machines, such as on-highway trucks, where space is limited. Further, the efficiency of electrical energy production by the system of the '028 patent may be lower than desired. In addition, newer high-efficiency thermoelectric materials have become available, and in order to maximize the power output that may be produced with these materials, improved heat transfer systems are needed.

The present disclosure is directed at overcoming one or more of the shortcomings of the prior art thermoelectric systems.

### SUMMARY OF THE INVENTION

One aspect of the present disclosure includes a thermoelectric power unit. The power unit may include at least one thermoelectric device. A first fluid passage may be disposed on a first side of the thermoelectric device and may be configured to receive a hot exhaust stream. The power unit may further include a plurality of heat pipes configured to focus thermal energy from a fluid flowing through the first passage toward the first side of the thermoelectric device. A second fluid passage may be disposed on a second side of the thermoelectric device opposite of the first fluid passage and configured to conduct thermal energy away from the thermoelectric device.

A second aspect of the present disclosure includes a method for generating electric power. The method may include providing a thermoelectric device proximate to a supply of thermal energy and creating a temperature differential across the thermoelectric device. The temperature differential may be created by supplying thermal energy to a first side of the thermoelectric device using a plurality of heat pipes configured to focus thermal energy from a fluid flowing through a first passage toward a first surface of the thermoelectric device, while extracting thermal energy from a second side of the thermoelectric device.

A third aspect of the present disclosure includes a thermoelectric generator. The generator may include a thermoelectric power unit including at least one thermoelectric device. A first fluid passage may be disposed on a first side of the thermoelectric device and may be configured to receive a hot exhaust stream. The power unit may further include a plurality of heat pipes configured to focus thermal energy from a fluid flowing through the first passage toward the first side of the thermoelectric device. A second passage may be disposed on a second side of the thermoelectric device opposite of the first passage. The generator may further include an exhaust supply passage configured to supply a hot exhaust gas stream to the first passage and at least one coolant passage configured to supply a cooling fluid to the second passage. One or more leads may form an electrical connection with the thermoelectric device.

### BRIEF DESCRIPTION OF THE DRAWINGS

FIG. 1A provides an exploded view of a thermoelectric generator system, according to an exemplary disclosed embodiment.

FIG. 1B provides a perspective view of the thermoelectric generator system of FIG. 1A.

FIG. 2 provides a perspective view of a set of thermoelectric power units, according to an exemplary disclosed embodiment.

FIG. 3A provides a perspective view of a thermoelectric device, according to an exemplary disclosed embodiment.

FIG. 3B provides a side view of a thermoelectric couple, according to an exemplary disclosed embodiment.

FIG. 3C provides a side view of a thermoelectric couple, according to an exemplary disclosed embodiment.

FIG. 3D provides a side view of a thermoelectric couple, according to an exemplary disclosed embodiment.

FIG. 3E provides a side view of a thermoelectric couple, according to an exemplary disclosed embodiment.

FIG. 3F provides a side view of a thermoelectric couple, according to an exemplary disclosed embodiment.

FIG. 4 provides a perspective view of a thermoelectric power unit, according to another exemplary disclosed embodiment.

FIG. 5 provides a partial side-end view of a thermoelectric power unit, according to an exemplary disclosed embodiment.

FIG. 6 provides a perspective view of a thermoelectric power unit, according to another exemplary disclosed embodiment.

### DETAILED DESCRIPTION

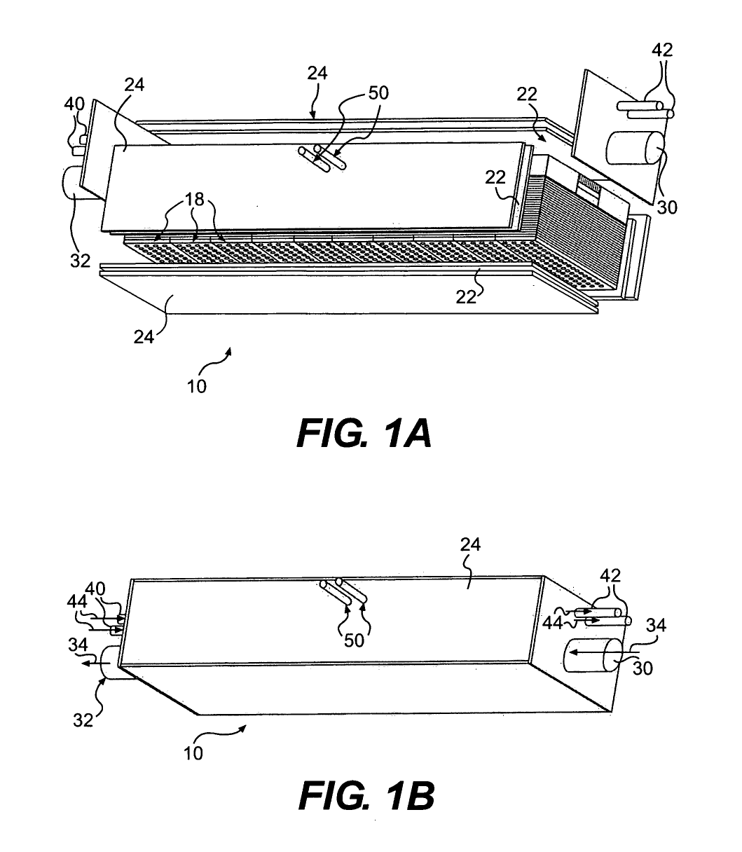

FIG. 1A provides an exploded view of a thermoelectric generator system 10, according to exemplary disclosed embodiment. As shown, generator system 10 may include one or more thermoelectric power units 18, as described below. Thermoelectric power units 18 may be surrounded by one or more layers of thermally-insulating material 22 and housed in a protective enclosure 24, as shown in FIG. 1B. Insulating materials 22 and enclosure materials may be selected based on a variety of factors including cost, durability, thermal conductivity, thermal expansion properties, and/or expected environmental stresses such as vibration, heat, and/or corrosion.

Generator system 10 may include one or more heating fluid intake passages 30 and heating fluid exit passages 32. Fluid intake passage 30 and fluid exit passage 32 may be operably connected to a hot fluid stream such as a vehicle engine exhaust system, thereby allowing hot exhaust to flow through thermoelectric power units 18.

In addition, generator system 10 may further include one or more cooling fluid intake 40 and cooling fluid exit passages 42. Intake passages 40 and exit passage 42 may be operably connected with a coolant supply system, such as a liquid coolant pump or air supply system. As shown, cooling fluid intake passage 40 and heating fluid intake passage 30 are positioned at opposite ends of generator unit 10. These positions may be selected to allow flow of heating and cooling fluids in opposite directions through thermoelectric power units 18. For example, as shown, hot fluid may flow in a first direction, as indicated by arrow 34, while a cooling fluid may flow in a second direction, as indicated by arrows 44. In some embodiments, oppositely-oriented fluid flow paths may increase the temperature differential and power output from the thermoelectric power unit contained therein.

Generator system 10 may further include one or more electrical leads 50. Electrical leads 50 may form electrical connections with thermoelectric devices 60, which may be contained within thermoelectric power units 18, as described below. Electrical leads 50 may allow electrical power to be derived from generator system 10. Electrical leads 50 may include any suitable lead type and may be configured for alternating current circuits or direct current circuits.

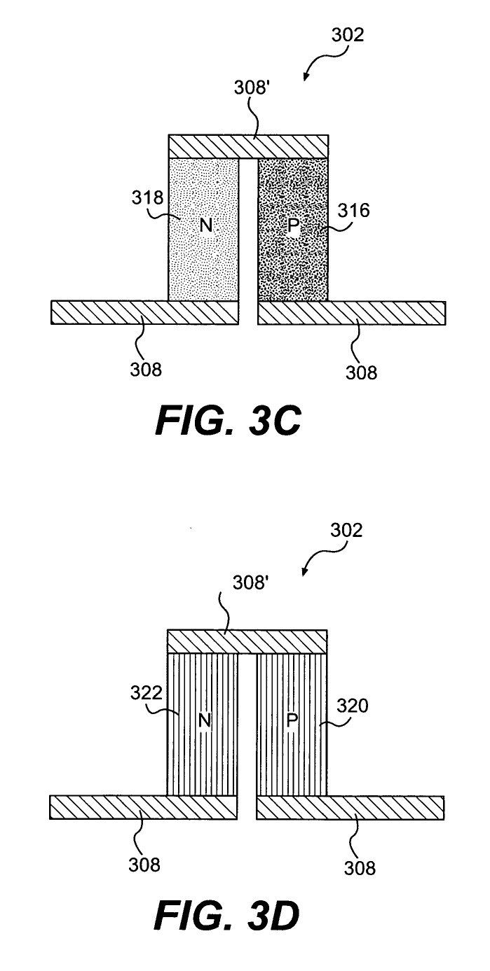

As noted, generator system 10 may include one or more thermoelectric power units 18. As shown in FIG. 1, generator system 10 includes ten thermoelectric power units 18, and each thermoelectric power unit may include one or more thermoelectric devices. The specific number of power units 18 may be selected based on a variety of factors, including cost, size constraints, desired power output, and available thermal energy. Any suitable number of power units 18 may be used. Further, it should be noted that although FIG. 1 illustrates the use of power units 18, as shown in FIG. 4, any of the disclosed power units may be selected.

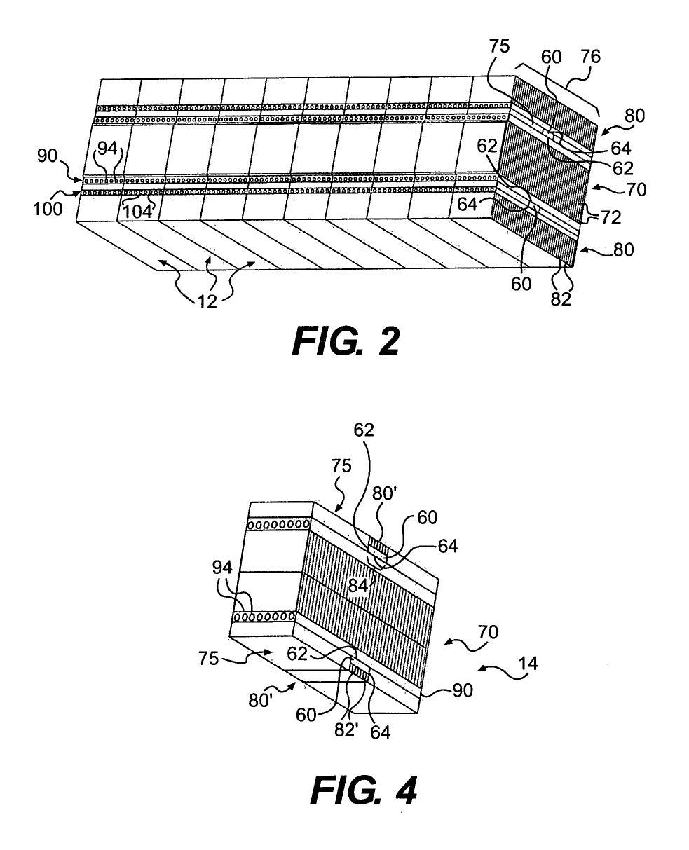

FIG. 2 provides a perspective view of a set of thermoelectric power units 12, according to an exemplary disclosed embodiment. The illustrated set of power units may be used with thermoelectric generator 10, or any other suitable generator. Further, the set may include any suitable number of power units 12.

As shown, thermoelectric power units 12 include one or more thermoelectric devices 60, having a first side 62 and second side 64. A first fluid supply passage 70 may be configured to receive a hot fluid stream and to supply thermal energy to first side 62 of thermoelectric devices 60. A second fluid passage 80 may be configured to receive a cooler fluid stream and to conduct heat away from second side 64 of the thermoelectric device 60. A thermally-insulating layer 75 may be configured to insulate the hot first passage 70 from the cooler second passage 80.

As shown power units 12 are aligned such that the first and second fluid passages 70, 80 of each power unit 12 are fluidly connected. Further, each power unit 12 may include one or more thermoelectric devices 60. For example, some power units 12 may include two or more thermoelectric devices 60 placed side-by-side. Thermoelectric devices 60 may be electrically connected with devices 60 of the same power unit 12 and/or with devices 60 of other power units within the same set. Further, any electrical circuit may be used, including series, parallel, or series-parallel combination.

Supplying heat to first side 62 of thermoelectric device 60 while extracting heat from second side 64 of thermoelectric device 60 may produce a temperature differential across thermoelectric device 60. Production of a temperature differential across suitable thermoelectric devices will produce an electrical potential, which may be used to generate electrical power.

A variety of suitable thermoelectric devices 60 may be selected for power units 12. For example, device 60 may be selected based on numerous factors, including for example, the optimum temperature range for power generation using the selected device, the device's thermal conductivity, resistance to damage from heat or vibration, cost, availability, desired power output, and/or any other suitable factor. Numerous thermoelectric devices are commercially available, and any suitable device may be selected.

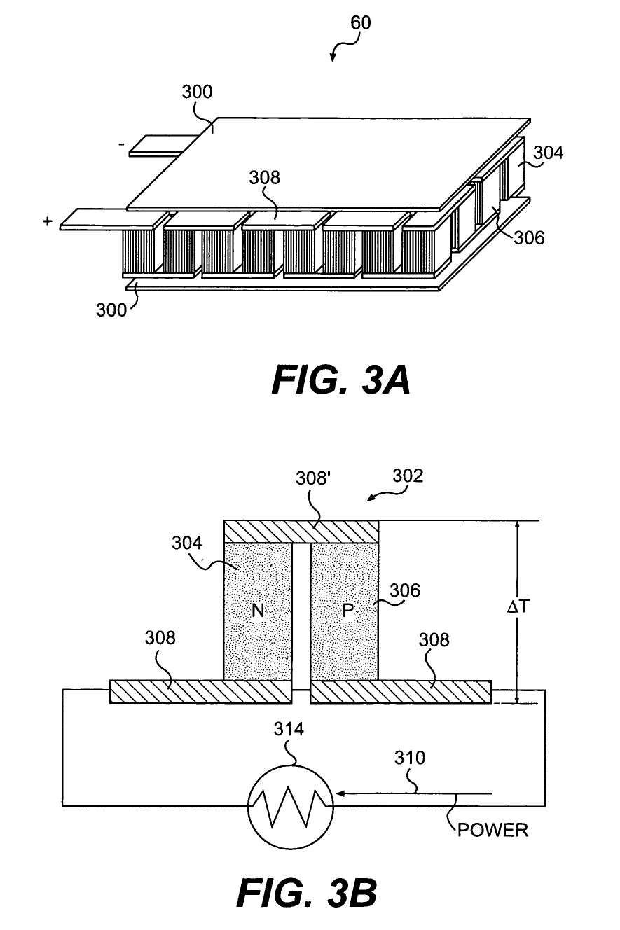

FIGS. 3A shows a typical thermoelectric device 60. The thermoelectric device consists of thermoelectric elements 304 and 306 arranged in a plurality of thermoelectric couples 302 (as shown in FIGS. 3B-3G) connected electrically in series and thermally in parallel using junctions 308. Thermoelectric devices 60 may include thermal plates 300 to support the structure and regulate the flow of heat into the thermoelectric couples.

Thermoelectric devices may be also called thermoelectric modules and may include a number of thermoelectriccouples 302. A thermoelectric element is a freestanding N type material 304 or P type material 306 in a pellet form. A thermoelectric couple 302 contains at least one N type thermoelectric element 304 and one P type thermoelectric element 306 joined together with a junction 308.

Thermoelectric materials may be operated based on the Seebeck effect. FIGS. 3B illustrate an exemplary configuration of thermoelectric materials operating based on the Seebeck effect. As shown in FIG. 3B, electrical power 310 may be generated through an electrical load 314 if a temperature difference AT is maintained between the opposing junctions 308, 308′ of thermoelectric couple 302 as shown. This temperature difference can be maintained by providing a heat source at one junction and a heat sink at the other junctions.

The effectiveness of a thermoelectric material in converting heat energy to electrical energy (conversion efficiency “η”) depends on the thermoelectric material's figure of merit termed “Z” and the average operating temperature “T”. Z is a material characteristic that is defined as:

$$Z = \frac{{S}^{2} σ}{λ} ,$$

where S is the Seebeck coefficient of the material, σ is the electrical conductivity of the material, and λ is the thermal conductivity of the material.

Because Z changes as a function of temperature, Z may be reported along with the temperature T, at which the properties are measured. Thus, the dimensionless product ZT may be used instead of Z to reflect the effectiveness of the thermoelectric material. To improve the η of thermoelectric materials, an increase in ZT may be necessary.

From the definition of Z, an independent increase in the Seebeck coefficient and/or electrical conductivity, or an independent decrease in the thermal conductivity may contribute to a higher ZT. Conventional low ZT thermoelectric materials, also known as bulk thermoelectric materials, may have ZT values that do not exceed one (1). Newly developed thermoelectric materials with low dimensional structures have demonstrated a higher figure of merit ZT that may approach 5 or more. These materials may include zero-dimensional quantum dots, one-dimensional nano wires, two-dimensional quantum well, superlattice and nanocomposite thermoelectric structures.

While bulk thermoelectric materials may be used in a thermoelectric generator, in certain embodiments, high ZT thermoelectric materials may also be used. High efficiency thermoelectric materials that may have ZT values between 1.0 and 10 may be provided consistent with the disclosed embodiments. The described ZT values are exemplary only and not intended to be limiting. High efficiency thermoelectric materials with other ZT values may also be used.

In one embodiment, as shown in FIG. 3C, thermoelectric couple 302 may include a P element 316 and an N element 318 that may be made of zero-dimensional quantum dots of lead-tin-selenium-telluride or other thermoelectric materials. In another embodiment, as shown in FIG. 3D, thermoelectric couple 302 may include a P element 320 and an N element 322 that may be made of one-dimensional nano wires of bismuth-antimony or other thermoelectric materials. In another embodiment, as shown in FIG. 3D, thermoelectric couple 302 may include a P element 324 and an N element 326 that may be made of two-dimensional quantum well or superlattice thermoelectric structures of boron carbide and silicon/silicon-germanium, respectively, or other thermoelectric materials.

As explained above, thermoelectric couple 302 may include thermoelectric materials having low dimensional structures, such as two-dimensional quantum wells, for example, illustrated as a series of parallel lines in FIGS. 3E-3F. Arrangement of the low dimensional structures relative to the flow of heat may be in-plane (i.e., the dimension is in a same direction of the flow of heat between junctions), as shown in FIG. 3E. Alternatively, the arrangement of the low dimensional structures relative to the flow of heat may also be cross-plane (i.e., the dimension is in a cross direction of the flow of heat between junctions), as shown in FIG. 3F.

It is understood that the disclosed structures of thermoelectric couple 302, the thermoelectric materials used, and the ZT values of the thermoelectric materials used are exemplary and not intended to be limiting. Other structures and thermoelectric materials may be included without departing from the principle and scope of disclosed embodiments. For example, in certain embodiments, thermoelectric couple 302 used by thermoelectric module 60 may include P elements with different structures from N elements. For instance, the P elements may be made of zero-dimensional quantum dots, while the N elements may be made of two-dimensional quantum well or superlattice thermoelectric structures.

Referring again to FIG. 2, fluid passage 70 may include one or more heat sinks 72, which may facilitate conduction of heat from passage 70. Any suitable heat sink configuration may be selected. For example, as shown, heat sinks 72 may include multiple fins configured to improve heat extraction from passage 70. A variety of suitable fin sizes, shapes, and configurations may be selected, and the specific fin design may be chosen based on cost, manufacturability, desired rate of heat conduction, and/or any other suitable factor.

Further, as shown, first passage 70 has a rectangular cross-sectional area and contains a number of heat sink fins 72. However, any suitable passage shape, passage size, and/or fin configuration may be selected. For example, the design of passage 70 and heat sink fins 72 may be selected to produce a desired degree of heating of thermoelectric device 60. Further, in some embodiments, the design of first passage 70 may be selected to limit resistance to flow, thereby preventing excess upstream back-pressures.

In some embodiments, thermoelectric power units 12 may further include a plurality of heat pipes 94 configured to increase thermal conductivity between thermoelectric device 60 and first passage 70. Heat pipes 94 may include a variety of suitable heat pipe designs and configurations. Generally, a heat pipe will include a hollow tube or cylinder filled with a vaporizable liquid. The liquid will be heated in one section of the tube and move towards a cooler portion of the tube where the thermal energy will be released and the liquid will condense.

Some heat pipes may be gravity assisted. In a gravity-assisted heat pipe, the liquid will be heated in a lower portion of the pipe, and the vapor will rise to a higher region where it will be cooled and condensed. Subsequently, the condensate will be pulled back towards the lower portion of the pipe to be reheated. Other heat pipes may be oriented horizontally. In horizontal heat pipes, the condensate will be drawn back to the hotter portions of the pipe by capillary action or wicking.

In some embodiments, heat pipes 94 may be configured to focus thermal energy from first passage 70 to a surface of thermoelectric device 60. For example, as shown, first passage 70 has a width 76 that is larger than the width of thermoelectric device 60. Further, as shown, heat pipes 94 are contained in a common base 90 of heat sink fins 72. In addition, heat pipes 94 may have a length, as measured along the common base of heat sink fins 72, that is longer than the width of the thermoelectric devices 60 and extends across heat sink common base 90. Further, heat pipes 94, having a length that extends across heat sink common base 90, may be configured to conduct heat from all heat sink fins 72, thereby allowing heat from a relatively large volume and across the entire width of fluid passage 70 to be conducted towards and focused on one side of thermoelectric device 60.

In addition, as shown in FIG. 2, heat pipes 94 are oriented parallel to first side 62 of thermoelectric device 60 and approximately horizontal with respect to the ground. This embodiment may be selected to reduce the vertical volume required by heat pipes 94, which may be desirable for applications that provided limited space. Further, horizontal heat pipes may allow power-generating, thermoelectric devices 60 to be disposed on multiple sides of thermoelectric power unit 12, as shown in FIGS. 2 and 4.

As noted, second fluid passage 80 may be in thermally-conductive connection with second side 64 of thermoelectric device 60. Second fluid passage 80 may be configured to receive a cooling fluid, such as air, water, and/or an engine coolant. Further, as shown, second fluid passage 80 may include a series of heat sink fins 82, which may increase conduction of heat away from thermoelectric device 60. Further, second fluid passage 80 may include a set of horizontally oriented heat pipes 104. Heat pipes 104 may be contained within a common base 100 of heat sink fins 82, thereby allowing conduction of heat away from thermoelectric device 60 and into heat sink fins 82.

As shown in FIG. 2, second fluid passage 80 is rectangular and has a width that is approximately equal to the width of first passage 70. However, a variety of suitable fluid passage configurations may be selected. For example, the passage size, passage shape, number of heat sink fins 82, number of heat pipes 94, heat pipe orientations, and/or cooling fluid type may be selected based on a variety of different factors. For example, the second passage design may be selected based on cost, desired degree of cooling, amount of heat provided from first passage 70, and/or any other suitable factor.

Further, as noted previously, a variety of different fluids may be selected for use as a coolant to flow through second fluid passage 80. For example, in some embodiments, the cooling fluid may include air, water, and/or a vehicle's coolant (e.g. water plus ethylene glycol). However, any suitable fluid may be selected. The specific fluid may be selected based on cost, desired specific heat of the cooling fluid, thermal conductivity, interaction with materials used to produce fins 82, and/or any other suitable factor.

Further, the flow of cooling fluid may be controlled in a variety of ways. For example, the cooling fluid may include free flowing air, such as environmental air outside of a moving highway vehicle. In other embodiments, the cooling fluid may be driven by a turbine or other type of fluid pump. Use of a turbine or other pump may provide control of cooling fluid flow. Such control may be desired when increased fluid flow is needed to increase heat removal or to help maintain the temperature differential of the device within a desired range. Further, if engine coolant is used as the cooling fluid, second passage 80 may be fluidly connected with an engine coolant system.

FIG. 4 provides a perspective view of a thermoelectric power unit 14 according to another exemplary disclosed embodiment. In this embodiment, like in the embodiment of FIG. 2, thermoelectric power unit 14 includes a thermoelectric device 60 having a first side 62 and second side 64. A first fluid passage 70 is disposed on a first side of thermoelectric device 60 and configured to supply thermal energy to thermoelectric device 60. Heat pipes 94 are configured to conduct thermal energy from heat supply passage 70 to thermoelectric device 60. Further, a second supply passage 80′ is disposed adjacent second side 64 of thermoelectric device 60 and is configured to conduct thermal energy away from second side 64, thereby producing a temperature differential across thermoelectric device 60.

As shown in FIG. 4, second fluid passage 80′ is disposed adjacent second side 64 of thermoelectric device 60. Further, passage 80′ may include a plurality of heat sink fins 82′ configured to increase conduction of thermal energy away from thermoelectric device 60. In addition, as in the embodiment of FIG. 2, second fluid passage 80′ may be configured to receive a variety of different cooling fluids. However, unlike the embodiment of FIG. 2, second fluid passage 80′ has a width 84 that is approximately equal to the width of thermoelectric device 60 such that the surface area of the opposing surfaces of second fluid passage 80′ and thermoelectric device 60 are approximately equal. This embodiment may be selected if a suitable degree of cooling may be achieved using liquid coolants flowing at a sufficient rate. Further, in some embodiments, a sufficient degree of cooling may be achieved without the added expense and complexity of heat pipes on the cooling side, while also using a smaller, less expensive set of heat sink fins 82′.

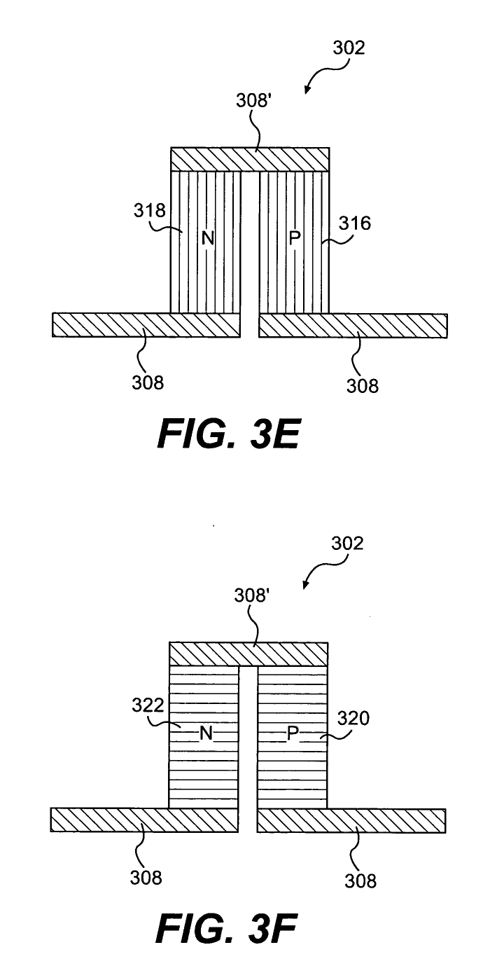

FIG. 5 provides a partial side-end view of a thermoelectric power unit 16, according to an exemplary disclosed embodiment. This embodiment is similar to the embodiment of FIG. 4 and includes first fluid passage 70, a thermoelectric device 60, and a cooling fluid passage 80′. Further, the device also includes a set of heat pipes 94′ contained within a common base 90′ of heat sink fins 72. In this embodiment, heat pipes 94′ are angled with respect to the thermoelectric device 60. In some embodiments, angled heat pipes 94′ may provide higher thermal conductivities than horizontal heat pipes (as shown in FIGS. 1, 2, and 4), which may be due to gravitational forces exerted on heat pipe condensates.

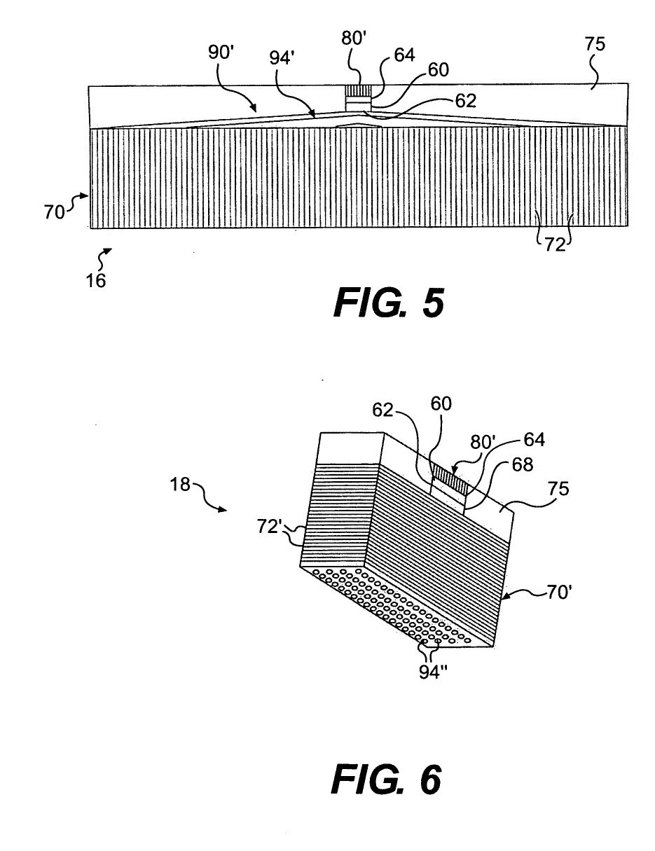

FIG. 6 provides a perspective view of a thermoelectric power unit 18, according to another exemplary disclosed embodiment. Again, this embodiment includes a heat supply passage 70′, a thermoelectric device 60, and second fluid passage 80′. In this embodiment, first passage 70′ includes vertically oriented heat pipes 94″. Vertically oriented heat pipes 94″ may be configured to conduct heat from all or part of first passage 70′ towards first side 62 of thermoelectric device 60.

For example, vertically-oriented heat pipes 94″ may include portions configured to traverse first passage 70 approximately perpendicular to thermoelectric device 60. Heat pipes 94″ may further include portions that are distributed or spaced apart within first passage 70′ and may converge at a common base 68 disposed adjacent thermoelectric device 60, thereby focusing heat conduction towards first side 62 of thermoelectric device 60. In some embodiments, first fluid passage 70′ may also include a plurality of heat sink fins 72′. As shown, heat sink fins 72′ are oriented perpendicular to heat pipes 94″, but heat sink fins 72′ may have any suitable size, shape, and/or orientation.

### INDUSTRIAL APPLICABILITY

This disclosure provides a thermoelectric power unit 12 and thermoelectric generator system 10 for production of electricity from thermal energy. The thermoelectric power unit 12 and generator system 10 may be used in any machine or system where thermal energy is produced.

Thermoelectric generator system 10 may be used to generate electrical energy from thermal energy. Thermoelectric generator system 10 may be used with any suitable source of thermal energy. For example, thermoelectric generator system 10 may be used to convert thermal energy in an engine exhaust passage into electrical power. Alternatively, thermoelectric generator system 10 may be used to produce power from any other thermal energy source, including for example, a geothermal power source, cooling water from a nuclear plant, hot gases released from a coal power plant, and/or any other suitable source.

The electrical power produced by thermoelectric generator system 10 may be used for a variety of different purposes. For example, thermoelectric generator system 10 may be used as an electric power source on a variety of different machines, including for example, on-highway or off-highway trucks, trains, earthmoving equipment, airplanes, and/or boats. In addition, thermoelectric generator system 10 may be incorporated into a generator set to further increase the power output and efficiency of the generator set. Further, the electric power may be used immediately or may be stored for later use.

The thermoelectric power unit 12 of the present disclosure can include heat pipes 94 for improving heat transfer from a heat source, such as an exhaust gas stream, to a first side 62 of a thermoelectric device 60. The power unit 12 may further include a cooling system for improving the transfer of heat away from a second side of the thermoelectric device. The power unit heat pipes 94 may include a variety of different configurations. For example, the heat pipes 94 may be oriented horizontally with respect to selected thermoelectric devices and/or the ground. Generally, horizontally-oriented heat pipes will function through an evaporation and wicking mechanism. This design may be selected to provide a compact system that will fit in small spaces, such as an engine compartment of a vehicle or under the body of an on-highway truck. Alternatively, the heat pipes 94 may be oriented vertically or at an angle with respect to selected thermoelectric devices and/or the ground. Vertically-oriented or angled designs may provide higher thermal conductivities than horizontal designs, thereby allowing higher power outputs, greater efficiency, and/or lower mass flow rate or temperature requirements for the heat source.

The thermoelectric power units 12 of the present disclosure may allow a large amount of thermal energy to be focused onto a relatively small thermoelectric device. This may allow efficient energy production with a high power density. This will further decrease the amount of expensive thermoelectric material required to meet electrical energy demands of mobile work machines, and since the thermoelectric materials may be the most expensive part of many thermoelectric generator systems, the thermoelectric power units 12 of the present disclosure may be produced at lower cost than other generator systems.

It will be apparent to those skilled in the art that various modifications and variations can be made in the disclosed systems and methods without departing from the scope of the disclosure. Other embodiments of the disclosed systems and methods will be apparent to those skilled in the art from consideration of the specification and practice of the embodiments disclosed herein. It is intended that the specification and examples be considered as exemplary only, with a true scope of the disclosure being indicated by the following claims and their equivalents.

What is claimed is:

1. A thermoelectric power unit, comprising:
at least one thermoelectric device;
a first fluid passage disposed on a first side of the thermoelectric device and configured to receive a hot exhaust stream;
a plurality of heat pipes configured to focus thermal energy from a fluid flowing through the first passage toward the first side of the thermoelectric device; and
a second fluid passage disposed on a second side of the thermoelectric device opposite of the first fluid passage and configured to conduct thermal energy away from the thermoelectric device.

2. The thermoelectric power unit of claim 1, wherein the second passage is configured to receive a fluid that is cooler than the hot exhaust stream.

3. The thermoelectric power unit of claim 2, wherein the fluid is water.

4. The thermoelectric power unit of claim 2, wherein the fluid is an engine coolant.

5. The thermoelectric power unit of claim 2, wherein the fluid is air.

6. The thermoelectric power unit of claim 1, wherein the heat pipes are oriented substantially parallel to a surface of the thermoelectric device.

7. The thermoelectric power unit of claim 6, wherein the heat pipes have a length which is greater than a width of the thermoelectric device.

8. The thermoelectric power unit of claim 1, wherein a portion of the heat pipes is oriented at an angle with respect to a surface of the thermoelectric device.

9. The thermoelectric power unit of claim 1, wherein at least a portion of the heat pipes is oriented perpendicular to a surface of the thermoelectric device.

10. The thermoelectric power unit of claim 9, wherein the heat pipes are distributed within a volume of the first passage and converge adjacent to a surface of the thermoelectric device.

11. The thermoelectric power unit of claim 1, wherein the first passage includes a plurality of heat sink fins.

12. The thermoelectric power unit of claim 1, wherein the second passage includes a plurality of heat sink fins.

13. The thermoelectric power unit of claim 12, wherein the second passage further includes a plurality of heat pipes.

14. The thermoelectric power unit of claim 1, wherein the thermoelectric device includes a thermoelectric material having a structure selected from at least one of a zero-dimensional quantum dot structure, one-dimensional nano wires structure, two-dimensional quantum well structure, a superlattice structure, and a nanocomposite thermoelectric structure.

15. The thermoelectric power unit of claim 1, wherein the thermoelectric device includes a bulk thermoelectric material.

16. A method of generating electric power, comprising:
providing a thermoelectric device proximate to a supply of thermal energy; and
creating a temperature differential across the thermoelectric device by supplying thermal energy to a first side of the thermoelectric device using a plurality of heat pipes configured to focus thermal energy from a fluid flowing through a first passage toward the first side of the thermoelectric device and extracting thermal energy from a second side of the thermoelectric device.

17. The method of claim 16, wherein the heat pipes are oriented substantially parallel to a surface of the thermoelectric device.

18. The method unit of claim 16, wherein the heat pipes have a length which is greater than a width of the thermoelectric device.

19. The method of claim 16, wherein a portion of the heat pipes is oriented at an angle with respect to a surface of the thermoelectric device.

20. The method of claim 16, wherein at least a portion of the heat pipes is oriented perpendicular to a surface of the thermoelectric device.

21. The method unit of claim 20, wherein the heat pipes are distributed within a volume of the first passage and converge adjacent to a surface of the thermoelectric device.

22. The method of claim 16, wherein the first passage includes a plurality of heat sink fins.

23. A thermoelectric generator system, comprising:
a thermoelectric power unit, including:
at least one thermoelectric device;
a first fluid passage disposed on a first side of the thermoelectric device and configured to receive a hot exhaust stream;
a plurality of heat pipes configured to focus thermal energy from a fluid flowing through the first passage toward the first side of the thermoelectric device; and
a second fluid passage disposed on a second side of the thermoelectric device opposite of the first passage;
at least one coolant passage configured to supply a cooling fluid to the second passage;
an exhaust supply passage configured to supply a hot exhaust gas stream to the first passage; and
one or more leads in electrical connection with the thermoelectric device.

24. The thermoelectric generator system of claim 23, wherein the heat pipes are oriented substantially parallel to a surface of the thermoelectric device.

25. The thermoelectric generator system of claim 23, wherein the heat pipes have a length which is greater than a width of the thermoelectric device.

26. The thermoelectric generator system of claim 23, wherein a portion of the heat pipes is oriented at an angle with respect to a surface of the thermoelectric device.

27. The thermoelectric generator system of claim 23, wherein at least a portion of the heat pipes is oriented perpendicular to a surface of the thermoelectric device.

28. The thermoelectric generator system of claim 23, wherein the cooling fluid includes at least one of air, water, and an engine coolant.

29. The thermoelectric generator system of claim 23, wherein the cooling fluid and exhaust gas stream flow in substantially opposite directions with respect to the thermoelectric device.

30. The thermoelectric generator system of claim 23, wherein the thermoelectric device includes a thermoelectric material having a structure selected from at least one of a zero-dimensional quantum dot structure, one-dimensional nano wires structure, two-dimensional quantum well structure, a superlattice structure, and a nanocomposite thermoelectric structure.

31. The thermoelectric generator system of claim 23, wherein the thermoelectric device includes a bulk thermoelectric material.
